(19) United States
(12) Patent Application Publication
(10) Pub. No.: US 2026/0173499 A1
(43) Pub. Date: Jun. 18, 2026

(54) INTEGRATED CIRCUIT STRUCTURE WITH REDUCED LEAKAGE PATH

(71) Applicants: TSMC NANJING COMPANY LIMITED, Nanjing (CN); TAIWAN SEMICONDUCTOR MANUFACTURING COMPANY, LTD., Hsinchu (TW)

(72) Inventors: Baorong JI, Nanjing City (CN); Jian ZHU, Nanjing City (CN); Chao-Jui WANG, Hsinchu County (TW)

(73) Assignees: TSMC NANJING COMPANY LIMITED, Nanjing (CN); TAIWAN SEMICONDUCTOR MANUFACTURING COMPANY, LTD., Hsinchu (TW)

(21) Appl. No.: 19/014,495

(22) Filed: Jan. 9, 2025

(30) Foreign Application Priority Data
Dec. 13, 2024 (CN) 202423084524.1

(51) Int. Cl. H10D 84/01; H01L 21/762; H10D 64/27; H10D 84/83

(52) U.S. Cl. CPC H10D 84/0188; H10D 64/514; H10D 84/83; H10W 10/014; H10W 10/17

(57) ABSTRACT

A method includes following steps. A trench is formed in a semiconductor substrate. The trench is filled with a trench filler material. The trench filler material has a recessed region recessed from a top surface of the trench filler material. A high-k dielectric layer is deposited over the semiconductor substrate and the trench filler material. A first portion of the high-k dielectric layer is removed from the recessed region of the trench filler material, while leaving a second portion of the high-k dielectric layer over the semiconductor substrate. A gate structure is over the second portion of the high-k dielectric layer.

### PRIORITY CLAIM AND CROSS-REFERENCE

The present application claims priority to China Application Serial Number 202423084524.1, filed Dec. 13, 2024, which is herein incorporated by reference in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 2A, 3A, 4A, 5A, 6A, 7A, 8A, 9A, 10A, 11A, 12A, 13A, and 14A illustrate top views of intermediate stages in the manufacturing process.

FIGS. 1B, 2B, 3B, 4B, 5B, 6B, 7B, 8B, 9B, 10B, 11B, 12B, 13B, and 14B illustrate cross-sectional views corresponding to the lines B-B in the “A” figures.

FIGS. 10C, 13C and 14C illustrate cross-sectional views corresponding to the lines C-C in the “A” figures.

FIGS. 15A and 16A illustrate top views of intermediate stages in the manufacturing process.

FIGS. 15B and 16B illustrate cross-sectional views corresponding to the lines B-B in the “A” figures.

FIGS. 17A and 18A illustrate top views of intermediate stages in the manufacturing process.

FIGS. 17B and 18B illustrate cross-sectional views corresponding to the lines B-B in the “A” figures.

FIGS. 19A and 20A illustrate top views of intermediate stages in the manufacturing process.

FIGS. 19B and 20B illustrate cross-sectional views corresponding to the lines B-B in the “A” figures.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits.

Shallow trench isolation (STI) is a technique used in integrated circuit (IC) fabrication to isolate different active regions of a wafer, which are areas where transistors and other components are formed. The STI process involves etching a trench into the substrate and then filling it with an insulating material, such as silicon dioxide, to electrically isolate the active regions from each other. However, during the fabrication process, various factors such as etching and/or chemical-mechanical polishing (CMP) may lead to formation of divots at boundaries between the STI regions and the active regions, which are small depressions or indentations that occur at the interface where the STI region and the active region meet. These divots may adversely affect the performance and/or reliability of semiconductor devices.

For example, when a high-k dielectric layer is globally deposited over the substrate and subsequently patterned into localized high-k gate dielectric layers, residues of the high-k dielectric material may become unintentionally trapped within these divots. This entrapment may increase the risk of leakage current paths from the active region to a gate structure over the STI region. To address this issue, the present disclosure in various embodiments provides additional photolithography and etching steps to remove the high-k dielectric residues trapped in the divots, thereby mitigating the potential leakage currents.

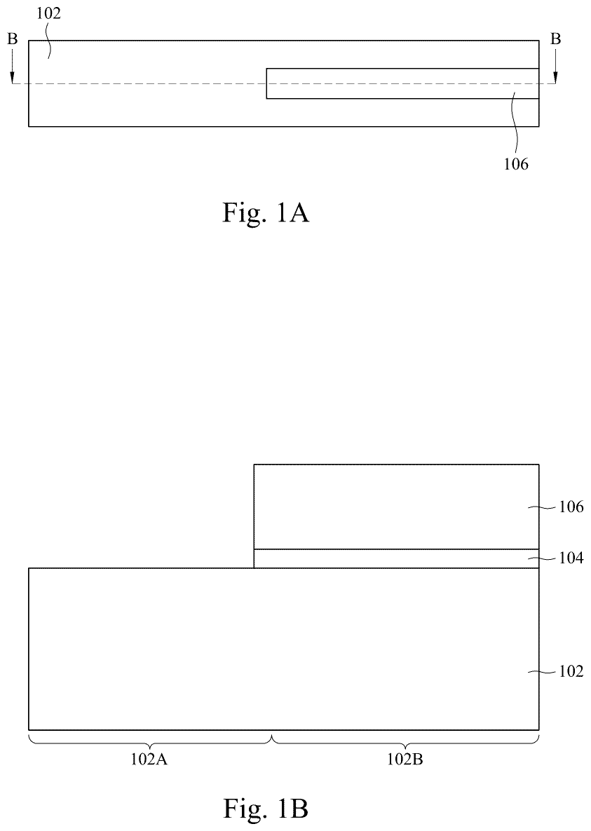

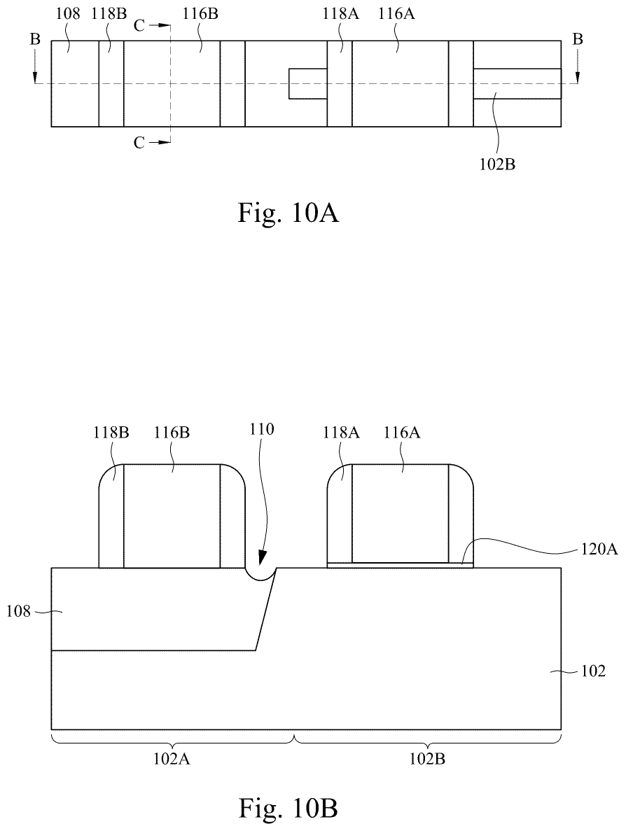

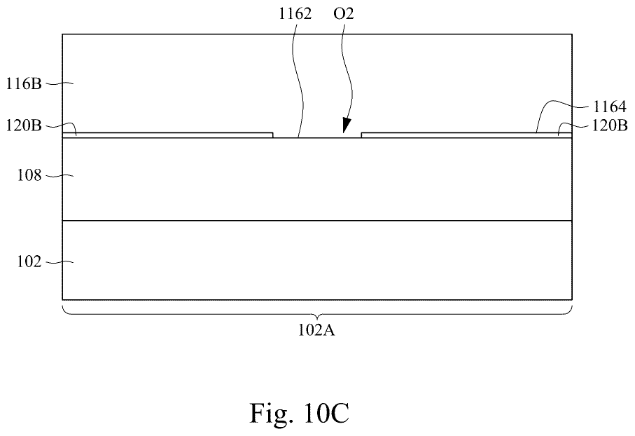

FIGS. 1A through 14C illustrate top views and cross-sectional views of intermediate stages in the manufacturing of an IC structure in accordance with some exemplary embodiments. FIGS. 1A, 2A, 3A, 4A, 5A, 6A, 7A, 8A, 9A, 10A, 11A, 12A, 13A, and 14A illustrate top views of intermediate stages in the manufacturing process. FIGS. 1B, 2B, 3B, 4B, 5B, 6B, 7B, 8B, 9B, 10B, 11B, 12B, 13B, and 14B illustrate cross-sectional views corresponding to the lines B-B in the “A” figures. FIGS. 10C, 13C and 14C illustrate cross-sectional views corresponding to the lines C-C in the “A” figures. It is understood that additional operations can be provided before, during, and after the processes shown by FIGS. 1A-14C, and some of the operations described below can be replaced or eliminated, for additional embodiments of the method. The order of the operations/processes may be interchangeable.

FIGS. 1A and 1B illustrate an initial structure for manufacturing the IC structure. The initial structure includes a substrate 102. The substrate 102 may be a semiconductor substrate, such as a bulk semiconductor, a semiconductor-on-insulator (SOI) substrate, or the like, which may be doped (e.g., with a p-type or an n-type dopant) or undoped. The substrate 102 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

FIGS. 1A and 1B further illustrates a pad layer 104 formed over the substrate 102 and a mask layer 106 formed over the pad layer 104. In some embodiments, the pad layer 104 may be a thin film comprising silicon oxide formed using, for example, a thermal oxidation process. The pad layer 104 may act as an adhesion layer between the substrate 102 and mask layer 106. The pad layer 104 may also act as an etch stop layer for etching the mask layer 106. In some embodiments, the mask layer 106 is formed of silicon nitride, for example, using low-pressure chemical vapor deposition (LPCVD) or plasma enhanced chemical vapor deposition (PECVD). The mask layer 106 is used as a hard mask during subsequent photolithography processes.

The pad layer 104 and mask layer 106 are patterned by using suitable photolithography and etching techniques. For example, a patterned photoresist layer is formed over the mask layer 106 by forming a photoresist material over the mask layer 106 using a spin-on coating process, followed by patterning the photoresist material by using suitable photolithography processes. For example, the photoresist material is irradiated (exposed) and developed to remove portions of the photoresist material. In greater detail, a photomask (not shown) may be placed over the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material, and a developer may be used to remove either the exposed or unexposed portions of the photoresist material depending on whether a positive or negative photoresist is used.

With the patterned photoresist in place, the mask layer 106 and the pad layer 104 are patterned using the patterned photoresist as an etch mask, thereby exposing a first region 102A of the substrate 102, while covering a second region 102B of the substrate 102. The first region 102A is referred to as an STI region on which STI dielectric material will be formed in subsequent processing, and the second region 102B is referred to as an active region on which functional transistors will be formed in subsequent processing.

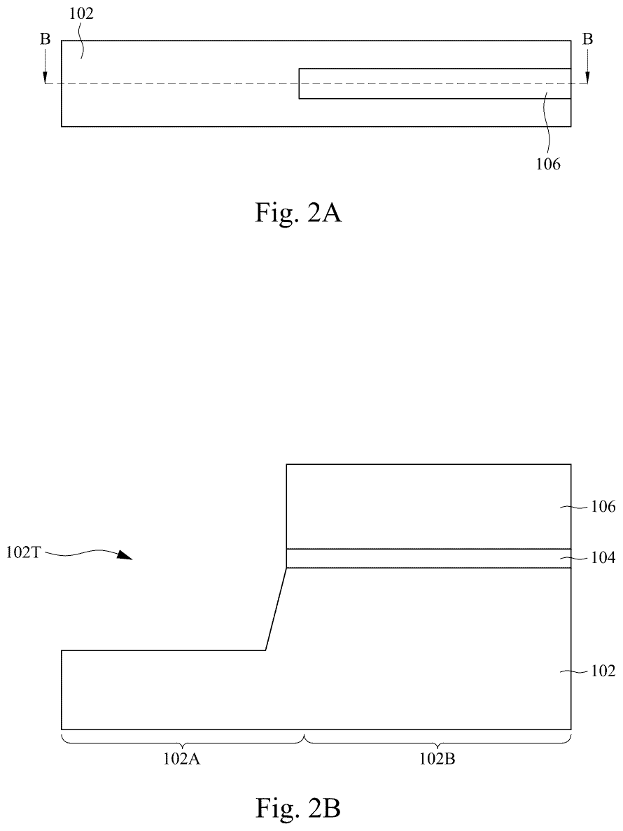

In FIGS. 2A and 2B, a trench 102T is etched in the exposed first region 102A of the substrate 102 by using the mask layer 106 as an etch mask. The etching may be any acceptable etch process, such as a reactive ion etch (RIE), neutral beam etch (NBE), the like, or a combination thereof. The etching may be anisotropic. After the etching is complete, the active region 102B has a sidewall inclined with respect to a bottom surface of the trench 102T.

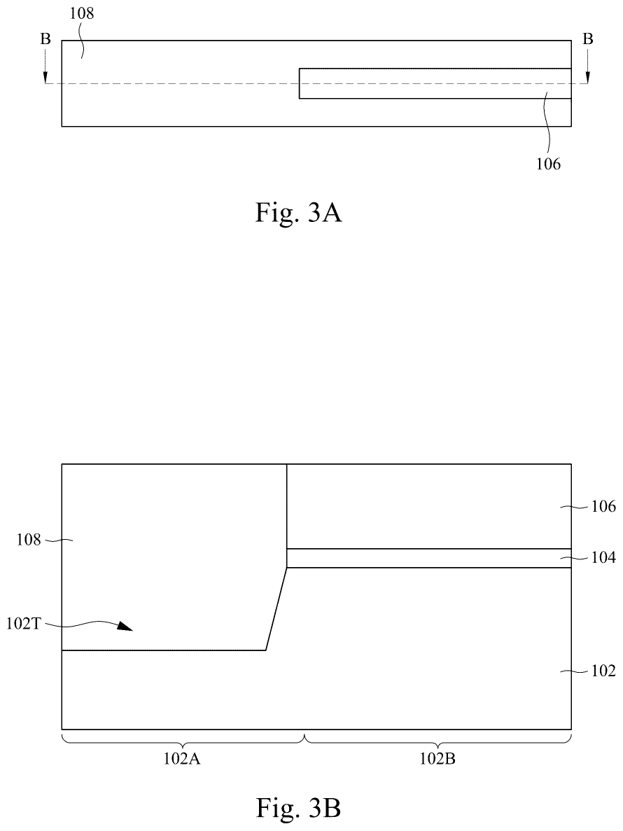

In FIGS. 3A and 3B, an STI filler material 108 is formed in the trench 102T within the first region 102A of the substrate 102. In some embodiments, the STI filler material 108 is formed from an insulation material, such as silicon oxide, a nitride, the like, or a combination thereof. The insulation material may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials formed by any acceptable process may be used. In the illustrated embodiment, the insulation material of the STI filler material 108 is silicon oxide formed by a FCVD process. An anneal process may be performed once the insulation material is formed. Although the insulation material of the STI filler material 108 is illustrated as a single layer, some embodiments may utilize multiple layers. For example, a liner (not shown) may first be formed along a surface of the substrate 102. Thereafter, a fill material, such as those discussed above may be formed over the liner. In some embodiments, after depositing the STI filler material 108 in the trench 102T, a CMP process is performed on the STI fill material 108 such that the STI filler material 108 has a top surface substantially level with a top surface of the mask layer 106.

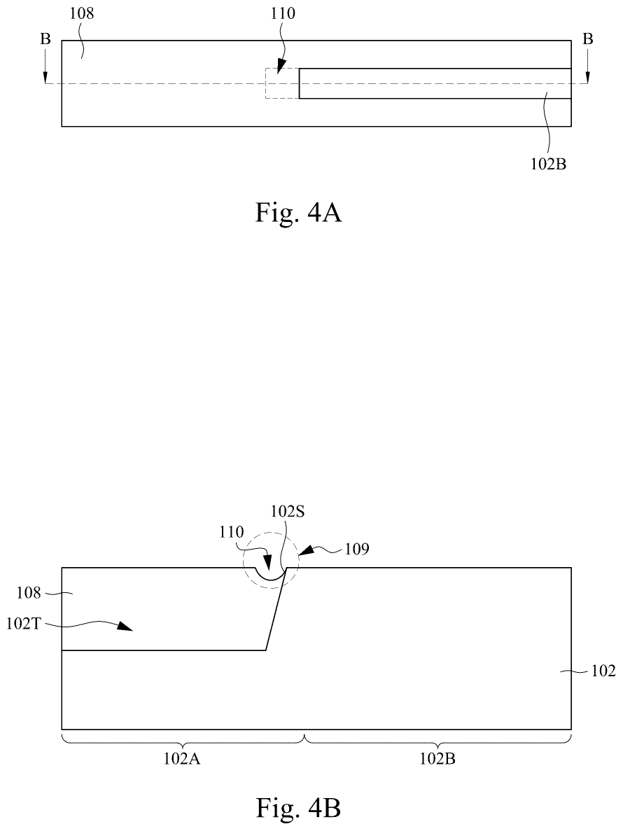

In FIGS. 4A and 4B, one or more etching processes are employed to remove the pad layer 104 and the mask layer 106, as well as to perform an etch-back of the STI filler material 108. Phosphoric acid (H₃PO₄) and hydrofluoric acid (HF) may be used as the etching solutions for the mask layer 106 (e.g., nitride material) and the pad layer 104 (e.g., oxide material), respectively. These etching processes, particularly the one targeting the pad layer 104, also remove the STI filler material 108 from the top surface of the substrate 102. As a result of this etch-back process, the top corners of the STI trench 102T experience significant removal of the STI filler material 108 at various locations 109 near the active region 102B. This creates divots (also referred to as recessed regions) 110 recessed from the top surface of the STI filler material 108 and potentially exposes an upper portion of a sidewall 102S of the active region 102B. This phenomenon occurs because the wet etch process etches along the interface between the substrate 102 and the STI filler material 108 at a faster rate than it does in other regions of the STI filler material 108.

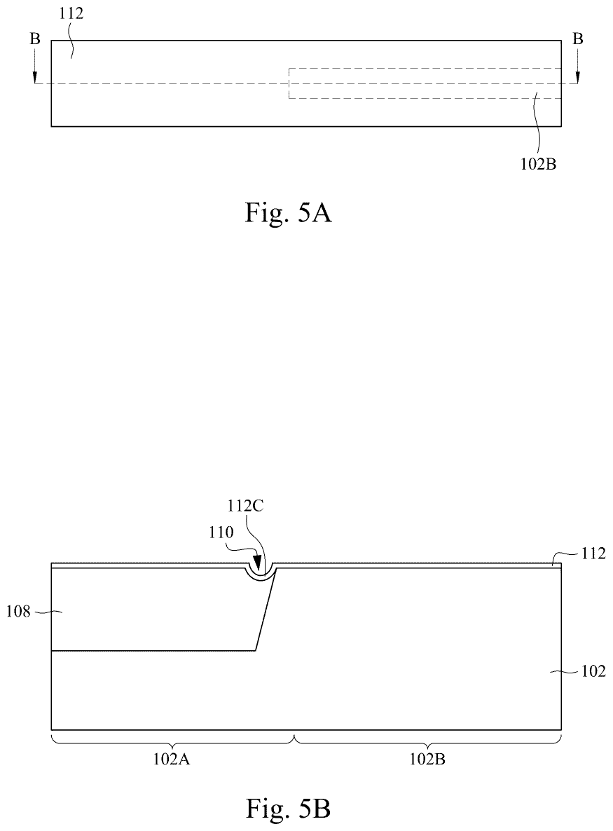

In FIGS. 5A and 5B, a high-k dielectric layer 112 is blanket deposited over the substrate 102, spanning both the STI region 102A and the active region 102B. The high-k dielectric layer 112 is in contact with and covers the active region 102B of the substrate 102 and the top surface of the STI filler material 108. In some embodiments, the high-k dielectric layer 112 includes a dielectric material having a high dielectric constant, for example, greater than that of thermal silicon oxide (˜3.9). The high-k dielectric layer 112 may include hafnium oxide (HfO₂). Alternatively, the high-k dielectric layer 112 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. The high-k dielectric layer 112 may be formed by atomic layer deposition (ALD), chemical vapor deposition (CVD), and/or other suitable method.

As illustrated in FIG. 5B, the high-k dielectric layer 112 has a concave section 112C within the divot 110 of the STI filler material 108. In some scenarios, this concave section 112C may come into contact with the sidewall of the active region 102B. This contact may increase the risk of leakage current paths from the active region 102B to a gate structure that will later be formed over the STI region 102A. This risk is higher compared to situations where the high-k dielectric layer 112 does not contact the sidewall of the active region 102B.

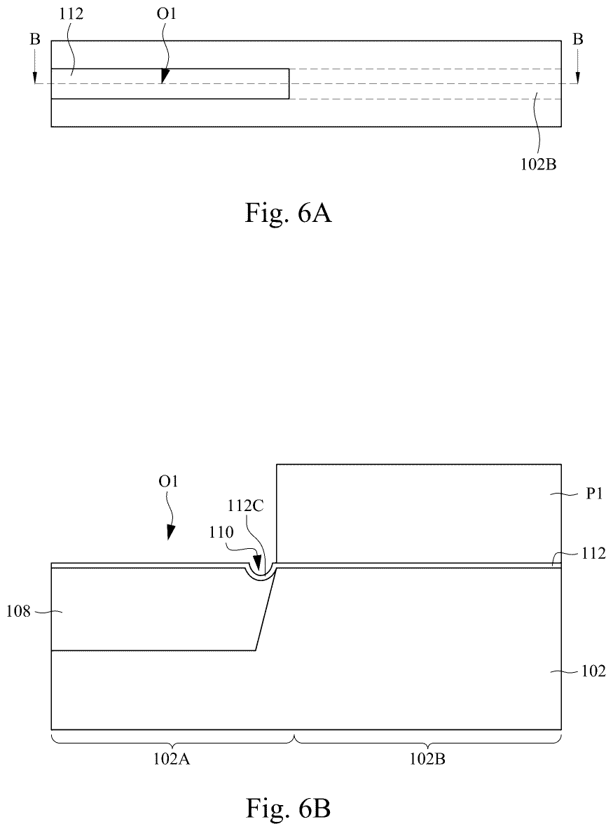

In FIGS. 6A and 6B, a patterned mask P1 is formed over the high-k dielectric layer 112. In some embodiments, the patterned mask P1 is a patterned photoresist formed using suitable photolithography process. In an example photolithography process, photoresist material is irradiated (exposed) and developed to remove portions of the photoresist material. In greater detail, a photomask or reticle (not shown) may be placed above the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material. A developer may be used to remove either the exposed or unexposed portions of the photoresist material depending on whether a positive or negative resist is used, leaving a patterned photoresist mask P1 over the high-k dielectric layer 112, with an opening O1 exposing a region of the high-k dielectric layer 112, which includes the concave section 112C.

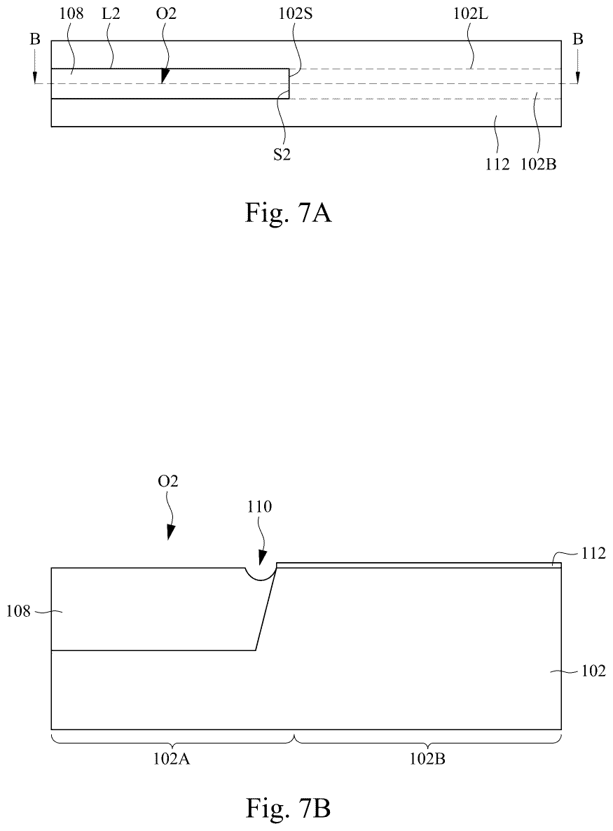

In FIGS. 7A and 7B, the high-k dielectric layer 112 is patterned in an etching process by using the patterned mask P1 as an etch mask, creating an opening O2 extending through the high-k dielectric layer 112 to expose a portion of the STI filler material 108. The etching process removes the concave section 112C of the high-k dielectric layer 112 from the divot 110, which in turn reduces the risk of leakage current paths from the active region 102B to a gate structure that will later be formed over the STI region 102A. The high-k dielectric layer 112 can be patterned by using suitable etching techniques, such as wet etching, dry etching, or combinations thereof. For example, a dry etching process for patterning the high-k dielectric layer 112, such as hafnium oxide (HfO₂), can be performed using a reactive ion etching (RIE) technique. In this process, a plasma containing fluorine-based gases, such as carbon tetrafluoride (CF₄), trifluoromethane (CHF₃), or sulfur hexafluoride (SF₆), can be used as etchants. These etching conditions can effectively etch the high-k dielectric layer 112 while minimizing damage to the exposed STI filler material 108.

After forming the opening O2 in the high-k dielectric layer 112, the patterned mask P1 can be removed, for example, using a plasma ash process. In some embodiments, a plasma ash process is performed such that the temperature of the photoresist is increased until the photoresist experiences a thermal decomposition and may be removed. However, any other suitable process, such as a wet strip, may be utilized.

In some embodiments, the opening O2 in the high-k dielectric layer 112 has a quadrilateral profile in a top view as illustrated in FIG. 7A. For example, the opening O2 has opposite longitudinal sides L2 and opposite transverse sides S2 shorter than the longitudinal sides L2. The active region 102B includes opposite longitudinal sides 102L and a transverse side 102S shorter than the longitudinal sides 102L and connecting the longitudinal sides 102L. As illustrated in the top view of FIG. 7A, a transverse side 102S of the active region 102B is in contact with the transverse side S2 of the opening O2. In this way, the transverse side 102S of the active region 102B is free of the high-k dielectric layer 112, thereby mitigating the potential leakage currents.

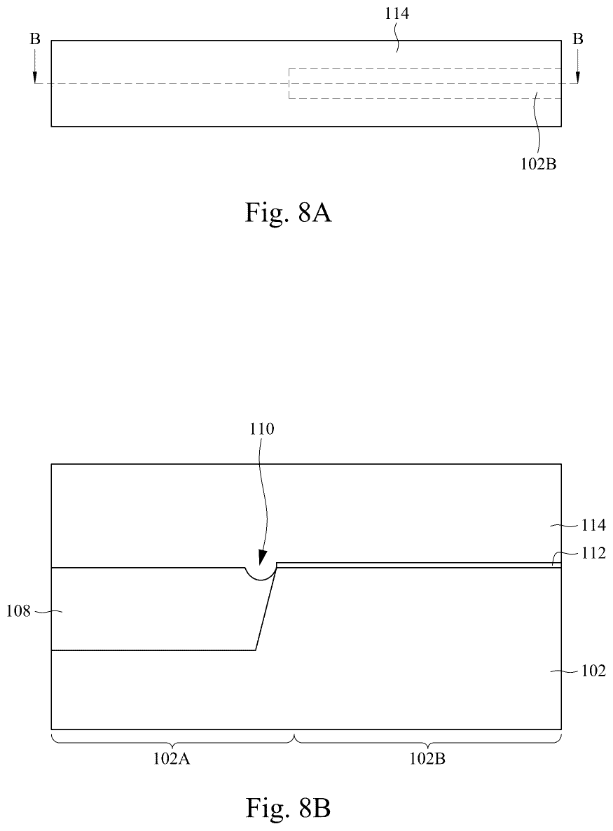

In FIGS. 8A and 8B, a dummy gate layer 114 is formed over the STI region 102A and the active region 102B. In some embodiments, the dummy gate layer 114 may be deposited, such as by using CVD or the like, over the STI filler material 108 and the high-k dielectric layer 112 and then planarized, such as by a CMP.

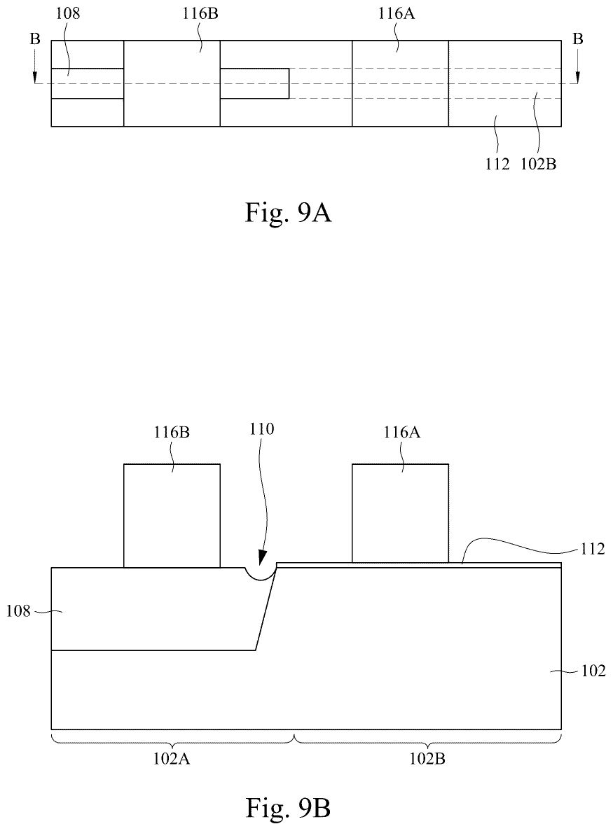

In FIGS. 9A and 9B, the dummy gate layer 114 is patterned using acceptable photolithography and etching techniques to form dummy gate structures 116A and 116B. The etching may comprise an acceptable anisotropic etching, such as RIE, NBE, or the like. The dummy gate structures 116A and 116B include a first dummy gate structure 116A overlapping a channel region of the active region 102B and a second dummy gate structure 116B non-overlapping the active region 102B. The first dummy gate structure 116A lands on and is in contact with the high-k dielectric layer 112, and the second dummy gate structure 116B lands on and is in contact with the STI filler material 108. The dummy gate structures 116A and 116B may have a lengthwise direction substantially perpendicular to the lengthwise direction of the active region 102B.

In some embodiments, the dummy gate layer 114 is patterned using a suitable etching process that will leave no or negligible polysilicon residue in the divot 110 in the STI region 102A, so as to mitigating potential leakage currents. For example, the etching process for patterning the dummy gate layer 114, which may include polysilicon, can involve a reactive ion etching (RIE) technique using a gas mixture of chlorine (Cl₂) and hydrogen bromide (HBr). This combination is effective for anisotropic etching of polysilicon, providing high selectivity to the underlying oxide material(s) and reducing polysilicon residues.

In FIGS. 10A and 10B, gate spacers 118A, 118B are formed on sidewalls of the dummy gate structures 116A, 116B, respectively. In some embodiments, one gate spacer 118B is formed adjacent the divot 110, but does not overlap with the divot 110. In some embodiments of the gate spacer formation step, a spacer material layer is deposited on the substrate 102. The spacer material layer may be a conformal layer that is subsequently etched back to form the gate spacers 118A and 118B. By way of example and not limitation, the spacer material(s) may be formed by depositing dielectric material(s) over the dummy gate structures 116A and 116B using suitable deposition processes such as, CVD process, a subatmospheric CVD (SACVD) process, a flowable CVD process, an ALD process, a PVD process, or other suitable process. An anisotropic etching process is then performed on the deposited dielectric material(s) to expose portions of the active region 102B not covered by the dummy gate structures 116A, 116B (e.g., in source/drain regions of the active region 102B. Portions of the spacer layer directly above the dummy gate structures 116 may be completely removed by this anisotropic etching process. Portions of the spacer layer sidewalls of the dummy gate structures 116A and 116B may remain, forming gate sidewall spacers, which are denoted as the gate spacers 118A and 118B, for the sake of simplicity.

In some embodiments, the high-k dielectric layer 112 is patterned in an etching process by using the dummy gate structures 116A, 116B and the gate spacers 118A, 118B as an etch mask, leaving a portion of the high-k dielectric layer 112 directly below the dummy gate structure 116A and the gate spacers 118A to serve as a high-k gate dielectric layer 120A as illustrated in FIG. 10B, and leaving two separate portions of the high-k dielectric layer 112 directly below the dummy gate structure 116B and gate spacers 118B to serve as high-k gate dielectric layers 120B separated by the opening O2 as illustrated in FIG. 10C. The high-k dielectric layer 112 can be etched using a selective etching process that attacks the high-k material, but hardly attacks the dummy gate structures 116A, 116B and the gate spacers 118A, 118B. For example, a selective etching process for etching high-k dielectric materials such as hafnium oxide (Hf₂) can be performed using a dry etching process such as a plasma etch with a fluorine-based chemistry, such as carbon tetrafluoride (CF₄) or trifluoromethane (CHF₃). These etchants selectively remove the hafnium oxide while leaving the polysilicon-based dummy gate structures 116A, 116B and the nitride-based gate spacers 118A, 118B substantially intact.

In the cross-sectional view of FIG. 10B, the resultant high-k gate dielectric layer 120A is in contact with an entirety of bottom surface of the dummy gate structure 116A. The high-k gate dielectric layer 120A laterally extends past opposite sidewalls of the dummy gate structure 116A and has opposite end surfaces substantially aligned with outermost sidewalls of the gate spacers 118A. On the other hand, in the cross-sectional view of FIG. 10B, the dummy gate structure 116B is in contact with STI filler material 108, and no high-k material interposes the dummy gate structure 116B and the STI filler material 108. However, in another cross-sectional view as illustrated in FIG. 10C, which is taken along a longitudinal axis of the dummy gate structure 116B, a bottom surface of the dummy gate structure 116B has a first region 1162 in contact with the STI filler material 108 and second regions 1164 in contact with the high-k dielectric layers 120B.

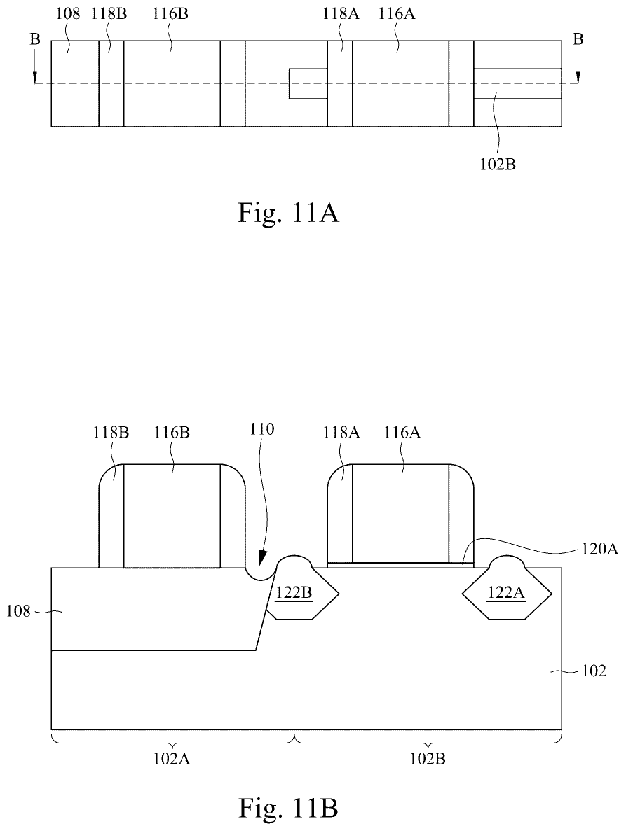

In FIGS. 11A and 11B, after patterning the high-k dielectric layer into high-k gate dielectric layers 120A, 120B, source/drain epitaxial structures 122A and 122B are formed on source/drain regions of the active region 102B that are not covered by the dummy gate structure 116A and the gate spacers 118A. In some embodiments, formation of the source/drain epitaxial structures 122A and 122B includes recessing source/drain regions of the active region 102B, followed by epitaxially growing semiconductor materials in the recessed source/drain regions of the active region 102B. The source/drain epitaxial structures 112A and 112B are illustrated in the cross-sectional view of FIG. 11B but not in the top view of FIG. 11A for the sake of clarity.

The source/drain regions of the active region 102B can be recessed using suitable selective etching processing that attacks the active region 102B, but hardly attacks the dummy gate structures 116A, 116B and the gate spacers 118A, 118B. For example, recessing the active region 102B may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the active region 102B at a faster etch rate than it etches the dummy gate structures 116A, 116B, and the gate spacers 118A, 118B. In some other embodiments, recessing the active region may be performed by a wet chemical etch, such as ammonium peroxide mixture (APM), NH₄OH, tetramethylammonium hydroxide (TMAH), combinations thereof, or the like, which etches the active region 102B at a faster etch rate than it etches the dummy gate structures 116A, 116B and the gate spacers 118A and 118B. In some other embodiments, recessing the active region may be performed by a combination of a dry chemical etch and a wet chemical etch.

Once recesses are created in the source/drain regions of the active region 102B, source/drain epitaxial structures 122A and 122B are formed in the source/drain recesses in the active region 102B by using one or more epitaxy or epitaxial (epi) processes that provides one or more epitaxial materials on the active region 102B. During the epitaxial growth process, the gate spacers 118A limit the one or more epitaxial materials to source/drain regions in the active region 102B. In some embodiments, the lattice constants of the epitaxial structures 122A, 122B are different from the lattice constant of the semiconductor material within the active region 102B, so that the channel region in the active region 102B and between the epitaxial structures 122A and 122B can be strained or stressed by the epitaxial structures 122A and 122B to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the semiconductor composition of the active region 102B. In some embodiments, the epitaxial structures 122A and 122B may have surfaces raised from the top surface of the active region 102B.

In some embodiments, the source/drain epitaxial structures 122A and 122B may include Ge, Si, GaAs, AlGaAs, SiGe, GaAsP, SiP, or other suitable material. The source/drain epitaxial structures 122A and 122B may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 122A and 122B are not in-situ doped, an implantation process (i.e., a junction implant process) is performed to dope the source/drain epitaxial structures 122A and 122B. In some exemplary embodiments, the source/drain epitaxial structures 122A and 122B in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed active region 102B in the p-type device regions. The mask may then be removed. Subsequently, a mask, such as a photoresist, may be formed over the p-type device region while exposing the n-type device regions, and n-type epitaxial structures may be formed on the exposed active region 102B in the n-type device region. The mask may then be removed.

Once the source/drain epitaxial structures 122A and 122B are formed, an annealing process can be performed to activate the p-type dopants or n-type dopants in the source/drain epitaxial structures 122A and 122B. The annealing process may be, for example, a rapid thermal anneal (RTA), a laser anneal, a millisecond thermal annealing (MSA) process or the like.

In some embodiments, as illustrated in FIG. 11B, the source/drain epitaxial structure 122B has a sidewall adjacent the divot 110 in the STI filler material 108. If there is a high-k dielectric residue trapped in the divot 110, it could potentially increase the risk of a leakage current path from the source/drain epitaxial structure 122B to the dummy gate structure 116B. However, by employing the processing steps illustrated in FIGS. 6A-7B, the divot 110 is effectively cleared of high-k dielectric residue, thereby mitigating the potential for leakage current.

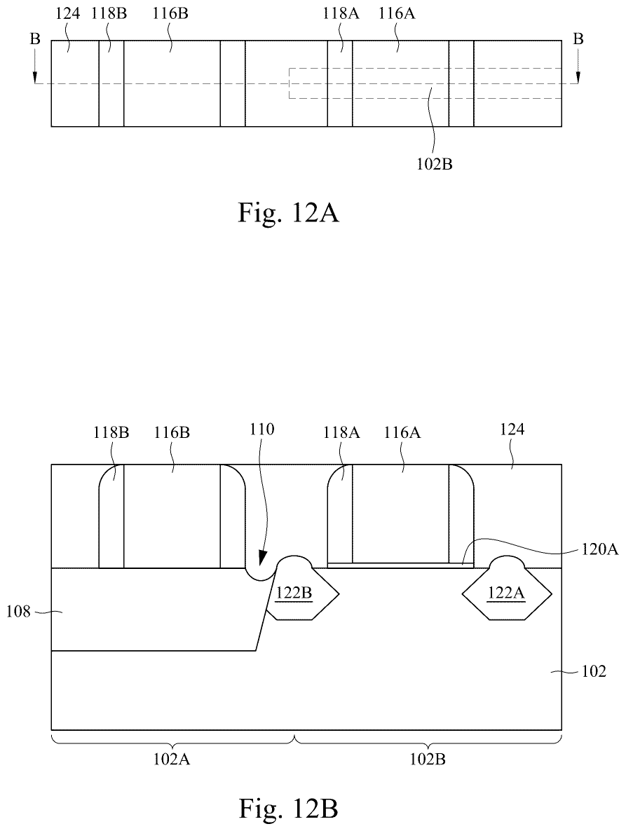

In FIGS. 12A and 12B, an interlayer dielectric (ILD) layer 124 is formed on the substrate 102. In some embodiments, a contact etch stop layer (CESL) is optionally formed prior to forming the ILD layer 124. In some examples, the CESL includes a silicon nitride layer, silicon oxide layer, a silicon oxynitride layer, and/or other suitable materials having a different etch selectivity than the ILD layer 124. The CESL may be formed by plasma-enhanced chemical vapor deposition (PECVD) process and/or other suitable deposition or oxidation processes. In some embodiments, the ILD layer 124 includes materials such as tetraethylorthosilicate (TEOS) formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL. The ILD layer 124 may be deposited by a PECVD process or other suitable deposition technique. In some embodiments, after formation of the ILD layer 124, the wafer may be subject to a high thermal budget process to anneal the ILD layer 124.

In some examples, after forming the ILD layer 124, a planarization process may be performed to remove excessive materials of the ILD layer 124. For example, a planarization process includes a chemical mechanical planarization (CMP) process which removes portions of the ILD layer 124 (and CESL, if present) overlying the dummy gate structures 116A and 116B until the dummy gate structures 116A and 116B get exposed.

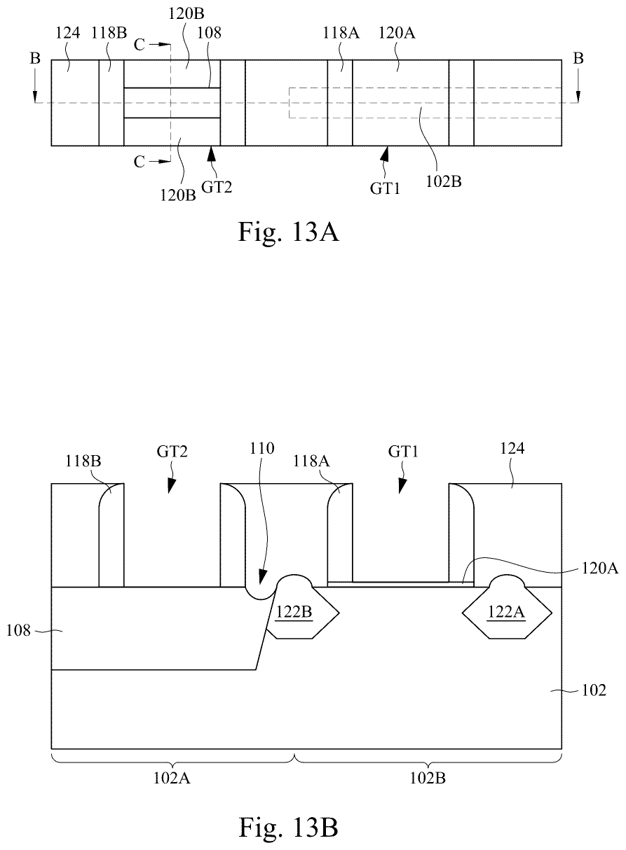

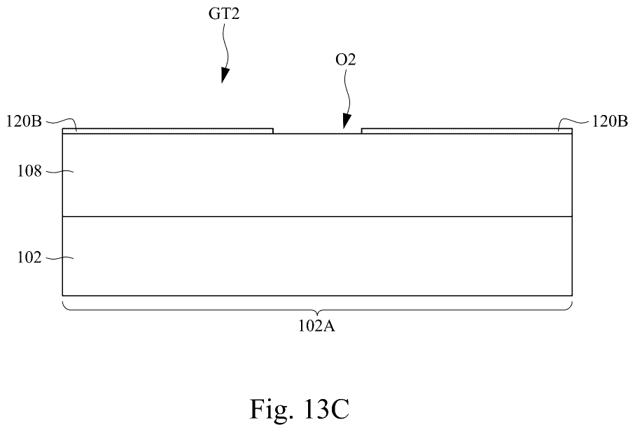

In FIGS. 13A-13C, the exposed dummy gate structures 116A, 116B are removed by one or more etching processes, resulting in a gate trench GT1 between gate spacers 118A, and a gate trench GT2 between the gate spacers 118B. In some embodiments, the dummy gate structures 116A and 116B are removed using a selective etching process (e.g., selective dry etching, selective wet etching, or a combination thereof) that etches materials in the dummy gate structures 116A, 116B at a faster etch rate than it etches other materials (e.g., gate spacers 118A, 118B and/or the ILD layer 124). As illustrated in FIGS. 13A-13C, in the active region 102B the high-k gate dielectric layer 120A is exposed at a bottom of the gate trench GT1 and occupies an entire footprint of the gate trench GT1 when viewed in the top view as illustrated in FIG. 13A; and in the STI region 102A the STI filler material 108 and the high-k gate dielectric layers 120B are exposed at a bottom of the gate trench GT2, and the high-k gate dielectric layers 120B occupy partial regions of footprint of the gate trench GT2, due to the high-k dielectric patterning process performed in the steps as illustrated in FIGS. 6A-7B.

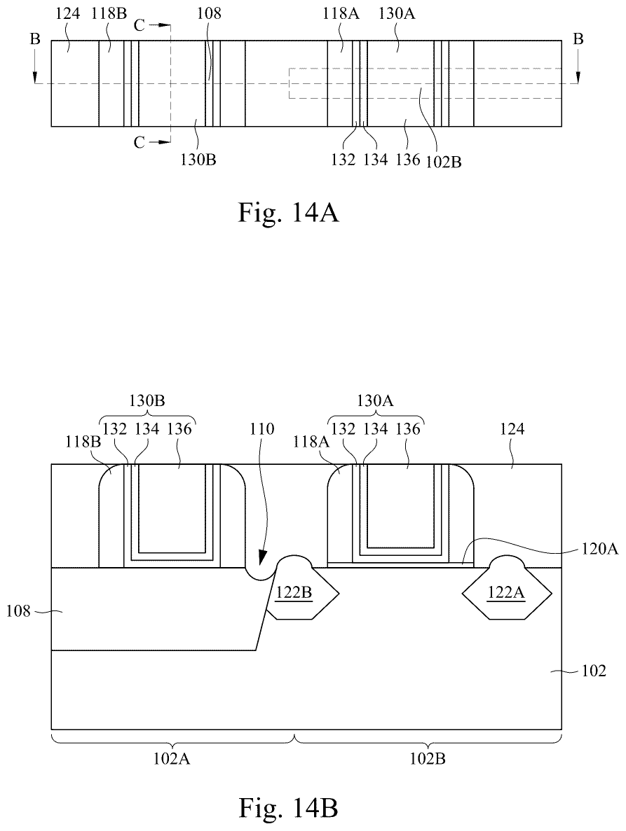

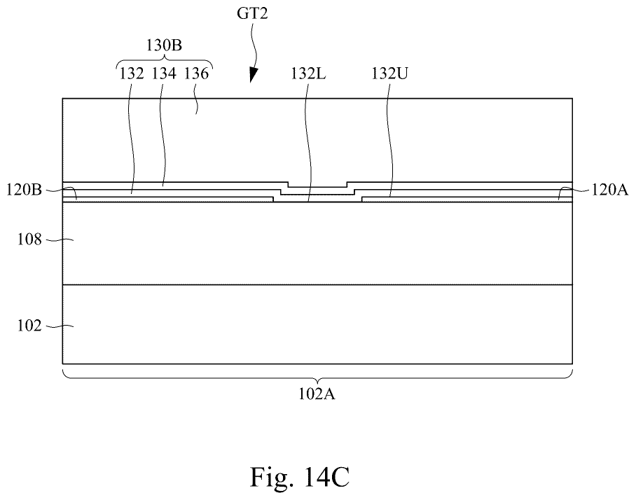

In FIGS. 14A-14C, replacement gate structures 130A and 130B are respectively formed in the gate trenches GT1 and GT2. The gate structure 130A may be a functional gate of a transistor formed on the active region 102B. The gate structure 130B may be a non-functional gate formed on the STI region 102A, or a functional gate of another transistor formed on another active region (not shown). The gate structures 130A and 130B each may form a high-k/metal gate (HKMG) stack with the underlying high-k gate dielectric layers 120A, 120B, however other compositions are possible. In some embodiments, the gate structure 130A forms the gate associated with the channel region between the source/drain epitaxial structures 122A and 122B. In various embodiments, the gate structures 130A and 130B each include one or more work function metal layers, including a first work function metal layer 132 over the high-k gate dielectric layers 120A, 120B, and a second work function metal layer 134 over the first work function metal layer 132, and a fill metal 136 formed over the work function metal layers 132, 134 and filling a remainder of the gate trenches GT1, GT2.

The work function metal layers 132, 134 and/or fill metal layer 136 used within gate structures 130A may include a metal, metal alloy, or metal silicide. Formation of the gate structures 130A and 130B may include multiple deposition processes to form various gate materials, one or more liner layers, and one or more CMP processes to remove excessive gate materials.

As illustrated in the cross-sectional view of FIG. 14B which is taken along line B-B perpendicular to a longitudinal axis of the gate structure 130B, the gate structure 130B comprises a work function metal layer 132 in contact with the STI filler material 108 in the STI region 102A, because in this cross-sectional view the gate structure 130B is free of a high-k gate dielectric layer due to the high-k dielectric patterning process performed in the steps as illustrated in FIGS. 6A-7B. As a result, in this cross-sectional view the work function metal layer 132 of the gate structure 130A has a bottom surface higher than a bottom surface of the work function metal layer 132 of the gate structure 130B. As illustrated in another cross-sectional view of FIG. 14C which is taken along line C-C parallel with the longitudinal axis of the gate structure 130B, the gate structure 130B comprises separate high-k gate dielectric layers 120B, and the work function metal layer 132 has a protruding portion extending through a region between the separate high-k gate dielectric layers 120B to reach the STI filler material 108 in the STI region 102A.

As illustrated in FIG. 14C, the gate structure 130B over the STI region 102A includes a work function metal layer 132 with a non-linear bottom surface. This non-linearity arises from the underlying topography created by the STI filler material 108 and the separate high-k gate dielectric layers 120B positioned over the STI filler material 108. Specifically, the non-linear bottom surface of the work function metal layer 132 has a lower portion 132L that extends through the gap between the high-k gate dielectric layers 120B to reach the STI filler material 108. Additionally, the non-linear bottom surface of the work function metal layer 132 further include upper portions 132U in contact with the top surfaces of the high-k gate dielectric layers 120B. In some embodiments, the work function metal layer 134 and the fill metal layer 136 may also exhibit similar non-linear bottom surfaces, as the work function metal layers 132 and 134 are formed using a conformal deposition technique.

In some embodiments, one or more of the work function metal layers 132, 134 may include work function metals to provide a suitable work function for the gate structures 130A and 130B. For an n-type FinFET, one or more of the work function metal layers 132, 134 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type FinFET, one or more of the work function metal layers 132, 134 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal 136 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

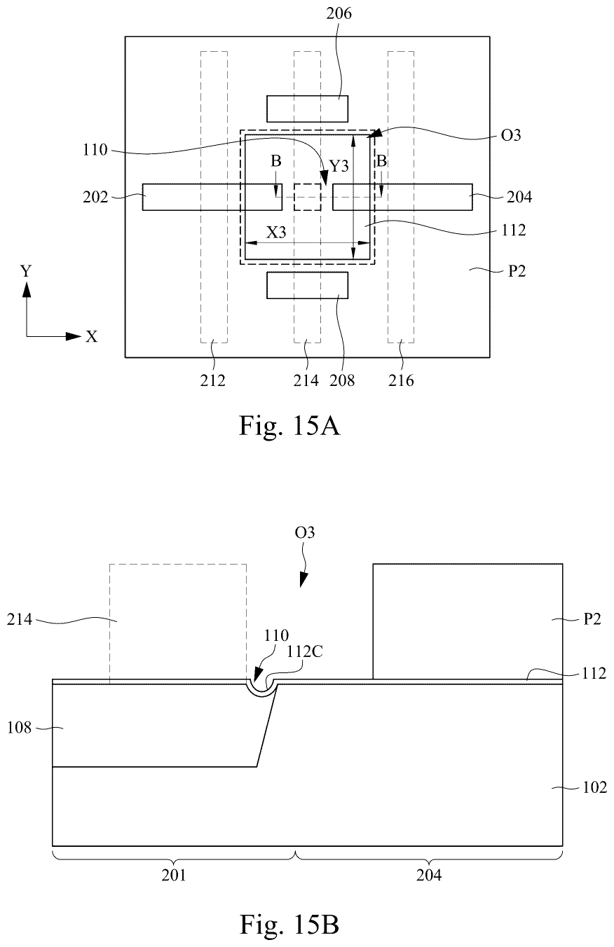

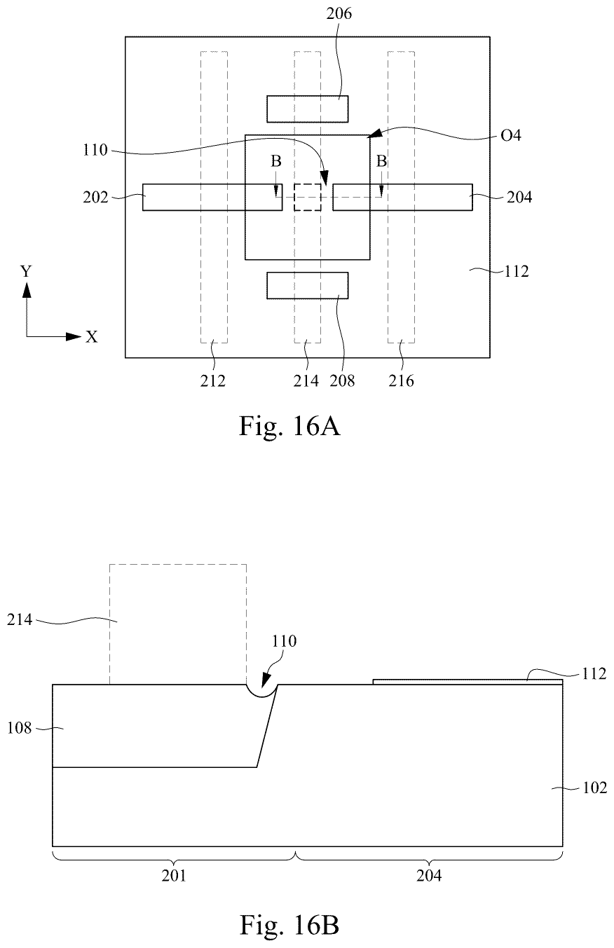

FIGS. 15A through 16B illustrate top views and cross-sectional views of intermediate stages in the manufacturing of an IC structure in accordance with some exemplary embodiments. FIGS. 15A and 15B illustrate a top view and a cross-sectional view of an intermediate stage of IC fabrication similar to that shown in FIGS. 6A and 6B, wherein FIG. 15B is a cross-sectional view taken along line B-B in FIG. 15A. The IC structure illustrated in FIGS. 15A and 15B includes four active regions 202, 204, 206, and 208 defined by an STI region 201 with the STI filler material 108 formed in the substrate 102. The active regions 202, 204, 206 and 208 extend in X-direction. The IC structure further includes three designated gate regions 212, 214, and 216 extending in Y-direction perpendicular to the X-direction. These designated gate regions 212, 214 and 216 are areas where dummy polysilicon gate structures will be formed and replaced with metal gate structures (e.g., the metal gate structures 130A or 130B as illustrated in FIGS. 14A-14C) in subsequent processing steps.

FIGS. 15A and 15B further illustrates a high-k dielectric layer 112 globally formed over the substrate 102, and a patterned mask P2 formed over the high-k dielectric layer 112. The IC structure includes a divot 110 in the STI filler material 108 at a boundary between the STI region 201 and an adjacent active region, e.g., the active region 204 as illustrated in FIG. 15B, and the high-k dielectric layer 112 has a concave section 112C within the divot 110 of the STI filler material 108. The patterned mask P2 has an opening O3 exposing a region of the high-k dielectric layer 112, which includes the concave section 112C.

From a top view, as depicted in FIG. 15A, the opening O3 has dimensions X3 and Y3 measured in the X and Y directions, respectively. In some embodiments, the X-directional dimension X3 of the mask opening O3 is greater than the X-directional dimension of the designated gate region 214 (i.e., the width of a polysilicon gate 116A or 116B) but less than the shortest X-directional distance between the designated gate regions 212 and 216. Similarly, the Y-directional dimension Y3 of the mask opening O3 is greater than the Y-directional dimension of the active region 202 or 204 but less than the shortest Y-directional distance between the active regions 206 and 208.

By designing the mask opening O3 with these specific dimensions, the subsequent patterning process on the high-k dielectric layer 112 can effectively remove the high-k material from the divot 110 without adversely impacting the remaining high-k gate dielectric material that serves for functional gates. FIG. 15A further illustrates a square S3 with a dotted outline corresponding to the maximal acceptable area of the mask opening O3, and a square S4 with a dotted outline corresponding to the minimal acceptable area of the mask opening O3. As illustrated in FIG. 15A, the dimension of square S3 is significantly larger than that of square S4, indicating that the mask opening O3 has a wide range of acceptable areas. This broad range relaxes the process window for patterning the high-k dielectric layer 112.

In FIGS. 16A and 16B, the high-k dielectric layer 112 is patterned in an etching process by using the patterned mask P2 as an etch mask, creating an opening O4 extending through the high-k dielectric layer 112 to expose a portion of the STI filler material 108. The etching process removes the concave section 112C of the high-k dielectric layer 112 from the divot 110, which in turn reduces the risk of leakage current paths from the active region 202 or 204 to a gate structure that will later be formed within the designated gate region 214.

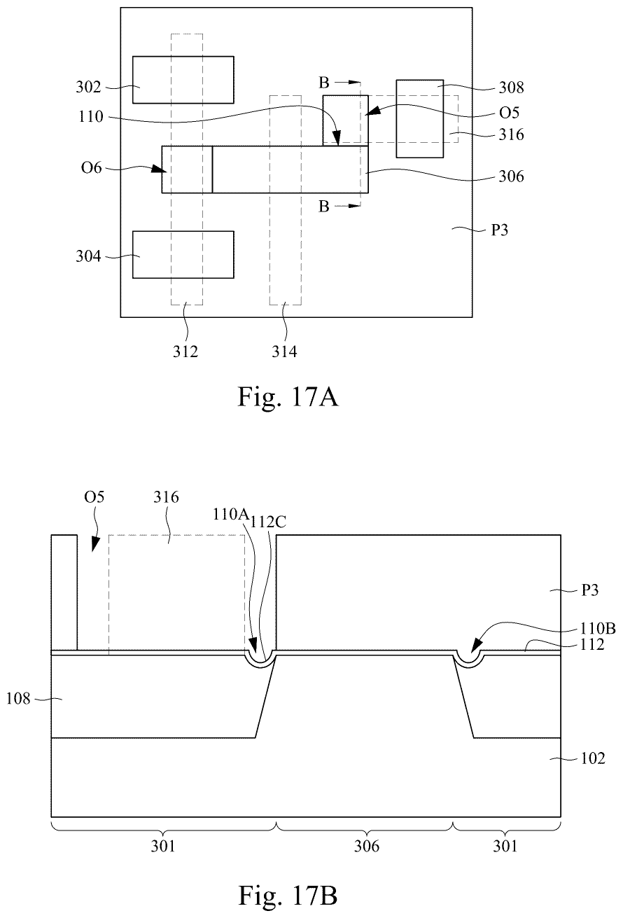

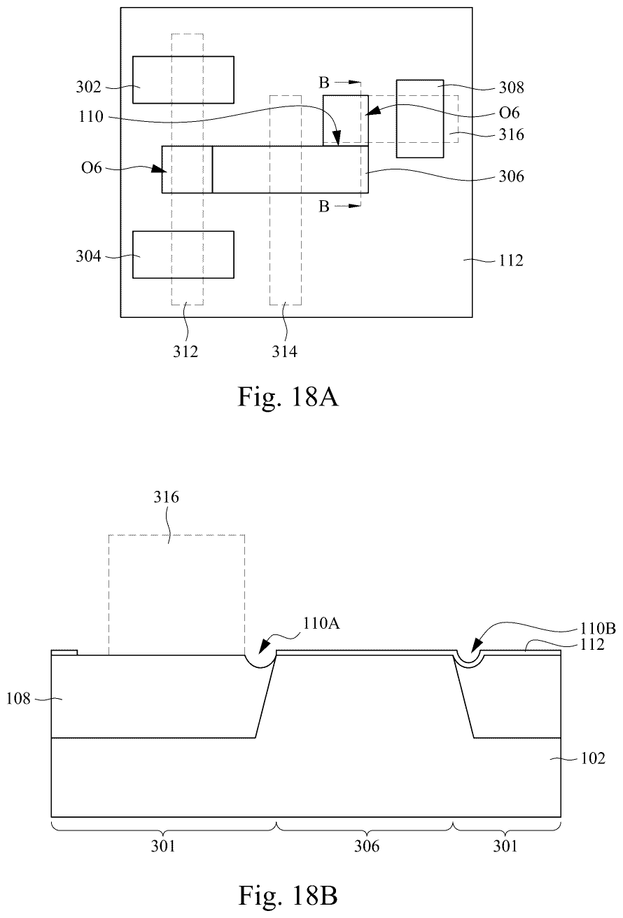

FIGS. 17A through 18B illustrate top views and cross-sectional views of intermediate stages in the manufacturing of an IC structure in accordance with some exemplary embodiments. FIGS. 17A and 17B illustrate a top view and a cross-sectional view of an intermediate stage of IC fabrication similar to that shown in FIGS. 6A and 6B, wherein FIG. 17B is a cross-sectional view taken along line B-B in FIG. 17A. The IC structure illustrated in FIGS. 17A and 17B includes four active regions 302, 304, 306, and 308 defined by an STI region 301 with the STI filler material 108 formed in the substrate 102. The active regions 302, 304, and 306 extend in X-direction, and the active region 308 extends in Y-direction perpendicular to X-direction. The IC structure further includes three designated gate regions 312 and 314 extending in Y-direction, and a designated gate region 316 extending in X-direction. These designated gate regions 312, 314 and 316 are areas where dummy polysilicon gate structures will be formed and replaced with metal gate structures (e.g., the metal gate structures 130A or 130B as illustrated in FIGS. 14A-14C) in subsequent processing steps.

FIGS. 17A and 17B further illustrates a high-k dielectric layer 112 globally formed over the substrate 102, and a patterned mask P3 formed over the high-k dielectric layer 112. The IC structure includes divots, such as a divot 110A in the STI filler material 108 at a boundary between the STI region 301 and the active region 306, and a divot 110B in the STI filler material 108 at a boundary between the STI region 301 and the active region 306. The divot 110A is adjacent to a designated gate region 316, while the divot 110B is not adjacent to any designated gate region. The high-k dielectric layer 112 has concave sections 112C respectively within the divots 110A and 110B.

The patterned mask P3 has openings O5 that expose regions of the high-k dielectric layer 112, including the concave section 112C within the divot 110A. In some embodiments, the concave section 112C within divot 110B remains covered by the patterned mask P3, as it is not adjacent to any designated gate region and thus poses no significant risk of leakage current.

In FIGS. 18A and 18B, the high-k dielectric layer 112 undergoes an etching process using the patterned mask P3 as an etch mask. This process creates openings O6 that extend through the high-k dielectric layer 112, exposing portions of the STI filler material 108. The etching removes the concave section 112C of the high-k dielectric layer 112 from divot 110A, thereby reducing the risk of leakage current paths from the active region 306 to a gate structure that will be subsequently formed in the designated gate region 316. Conversely, the concave section 112C within divot 110B remains intact, as it is not adjacent to any designated gate region and thus will not contribute to leakage current.

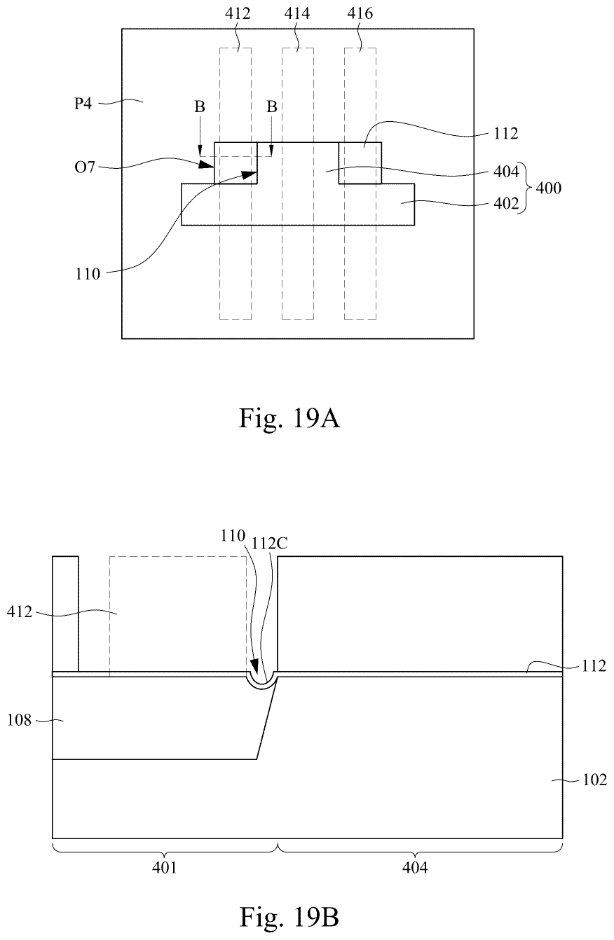

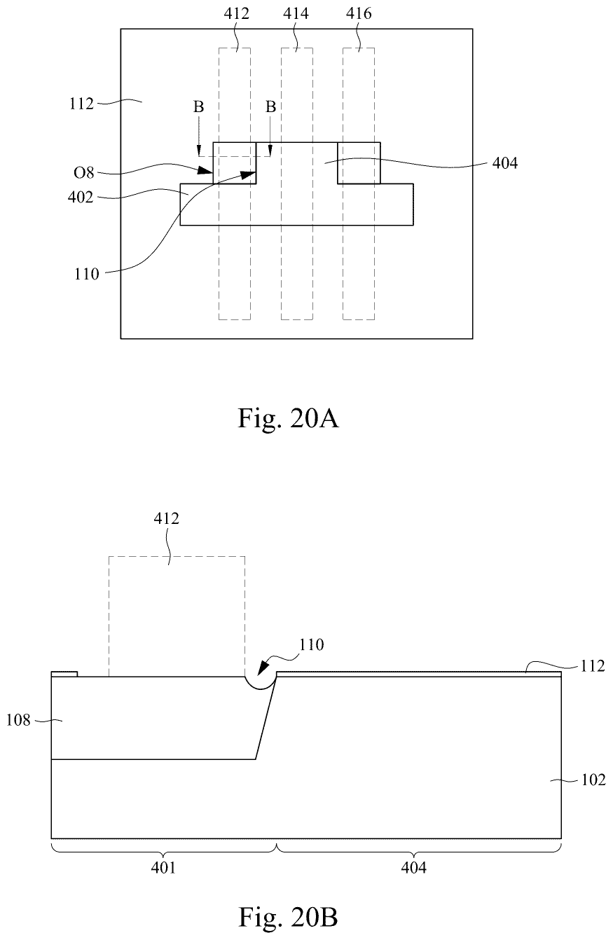

FIGS. 19A through 20B illustrate top views and cross-sectional views of intermediate stages in the manufacturing of an IC structure in accordance with some exemplary embodiments. FIGS. 19A and 19B illustrate a top view and a cross-sectional view of an intermediate stage of IC fabrication similar to that shown in FIGS. 6A and 6B, wherein FIG. 19B is a cross-sectional view taken along line B-B in FIG. 19A. The IC structure illustrated in FIGS. 19A and 19B includes an active region 400 with an irregular pattern defined by an STI region 401 with the STI filler material 108 formed in the substrate 102. The active region 400 includes a first active region 402 extending in X-direction and a second active region 404 protruding from a longitudinal side of the first active region 402 when viewed from above. The second active region 404 extends in X-direction and has a smaller length than the first active region 402. The second active region 404 thus has opposite side surfaces respectively set back from opposite side surfaces of the first active region 402. The IC structure further includes three designated gate regions 412, 414, and 416 extending in Y-direction. These designated gate regions 412, 414 and 416 are areas where dummy polysilicon gate structures will be formed and replaced with metal gate structures (e.g., the metal gate structures 130A or 130B as illustrated in FIGS. 14A-14C) in subsequent processing steps.

FIGS. 19A and 19B further illustrates a high-k dielectric layer 112 globally formed over the substrate 102, and a patterned mask P4 formed over the high-k dielectric layer 112. The IC structure includes divots, such as a divot 110 in the STI filler material 108 at a boundary between the STI region 401 and the second active region 404. The divot 110 is adjacent to a designated gate region 412, and the high-k dielectric layer 112 has a concave section 112C within the divot 110. The patterned mask P4 has openings O7 that expose regions of the high-k dielectric layer 112, including the concave section 112C within the divot 110.

In FIGS. 20A and 20B, the high-k dielectric layer 112 is patterned in an etching process by using the patterned mask P4 as an etch mask, creating openings O8 extending through the high-k dielectric layer 112 to expose portions of the STI filler material 108. The etching process removes the concave section 112C of the high-k dielectric layer 112 from the divot 110, which in turn reduces the risk of leakage current paths from the second active region 404 to a gate structure that will later be formed within the designated gate region 412.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is no or negligible high-k dielectric residue is trapped in divots in STI regions. Another advantage is that the risk of leakage current paths from the active regions to a gate structure over the STI regions can be mitigated due to the reduced high-k dielectric residues trapped in divots in STI regions.

In some embodiments, a method includes forming a trench in a semiconductor substrate; filling the trench with a trench filler material, the trench filler material having a recessed region recessed from a top surface of the trench filler material; depositing a high-k dielectric layer over the semiconductor substrate and the trench filler material; removing a first portion of the high-k dielectric layer from the recessed region of the trench filler material, while leaving a second portion of the high-k dielectric layer over the semiconductor substrate; and forming a gate structure over the second portion of the high-k dielectric layer. In some embodiments, the method further includes forming gate spacers at opposite sidewalls of the gate structure after removing the first portion of the high-k dielectric layer. In some embodiments, the gate spacers are formed over the second portion of the high-k dielectric layer. In some embodiments, the method further includes removing a portion of the second portion of the high-k dielectric layer that is not covered by the gate structure and the gate spacers. In some embodiments, the method further includes forming source/drain epitaxial structures on the semiconductor substrate after removing the first portion of the high-k dielectric layer. In some embodiments, the gate structure includes a polysilicon structure, and the method further includes replacing the polysilicon structure with a metal structure. In some embodiments, the method further includes prior to removing the first portion of the high-k dielectric layer, forming a patterned mask over the second portion of the high-k dielectric layer, while leaving the first portion of the high-k dielectric layer exposed. The first portion of the high-k dielectric layer is etched by using the patterned mask as an etch mask. In some embodiments, the method further includes removing the patterned mask prior to forming the gate structure.

In some embodiments, a method includes forming an isolation region abutting an active region in a substrate, the isolation region having a recessed region set back from a top surface of the isolation region; forming a high-k dielectric layer over the active region but not over the recessed region of the isolation region; forming a gate structure over the high-k dielectric layer; and forming gate spacers at opposite sidewalls of the gate structure and over the high-k dielectric layer. In some embodiments, forming the high-k dielectric layer comprises depositing a high-k dielectric layer over the isolation region and the active region, and etching the high-k dielectric layer to remove a portion of the high-k dielectric layer from the recessed region of the isolation region. In some embodiments, the portion of the high-k dielectric layer is in contact with a sidewall of the active region. In some embodiments, etching the high-k dielectric layer is performed by using a patterned photoresist as an etch mask. In some embodiments, the recessed region of the isolation region is adjacent to the active region. In some embodiments, the method further includes patterning the high-k dielectric layer into a gate dielectric layer by using the gate spacers and the gate structure as an etch mask. In some embodiments, the method further includes after patterning the high-k dielectric layer into the gate dielectric layer, replacing the gate structure with a metal gate structure.

In some embodiments, an IC structure includes an STI region, a first gate structure, and a second gate structure. The STI region abuts an active region in a semiconductor substrate. The first gate structure is over the active region. The first gate structure includes a high-k gate dielectric layer and a gate metal layer over the high-k gate dielectric layer. The second gate structure is over the STI region. In a cross-sectional view taken along a first direction perpendicular to a longitudinal axis of the second gate structure, the second gate structure includes a gate metal layer in contact with the STI region. In some embodiments, in the cross-sectional view the second gate structure is free of a high-k gate dielectric layer. In some embodiments, in the cross-sectional view the gate metal layer of the first gate structure has a bottom surface higher than a bottom surface of the gate metal layer of the second gate structure. In some embodiments, in a cross-sectional view taken along a second direction parallel with the longitudinal axis of the second gate structure, the second gate structure includes separate high-k gate dielectric layers, and a protruding portion of the gate metal layer extends through a region between the high-k gate dielectric layers to the STI region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a trench in a semiconductor substrate;
filling the trench with a trench filler material, the trench filler material having a recessed region recessed from a top surface of the trench filler material;
depositing a high-k dielectric layer over the semiconductor substrate and the trench filler material;
removing a first portion of the high-k dielectric layer from the recessed region of the trench filler material, while leaving a second portion of the high-k dielectric layer over the semiconductor substrate; and
forming a gate structure over the second portion of the high-k dielectric layer.

2. The method of claim 1, further comprising:
forming gate spacers at opposite sidewalls of the gate structure after removing the first portion of the high-k dielectric layer.

3. The method of claim 2, wherein the gate spacers are formed over the second portion of the high-k dielectric layer.

4. The method of claim 2, further comprising:
removing a portion of the second portion of the high-k dielectric layer that is not covered by the gate structure and the gate spacers.

5. The method of claim 1, further comprising:
forming source/drain epitaxial structures on the semiconductor substrate after removing the first portion of the high-k dielectric layer.

6. The method of claim 1, wherein the gate structure includes a polysilicon structure.

7. The method of claim 6, further comprising:
replacing the polysilicon structure with a metal structure.

8. The method of claim 1, further comprising:
prior to removing the first portion of the high-k dielectric layer, forming a patterned mask over the second portion of the high-k dielectric layer, while leaving the first portion of the high-k dielectric layer exposed,
wherein the first portion of the high-k dielectric layer is etched by using the patterned mask as an etch mask.

9. The method of claim 8, further comprising:
removing the patterned mask prior to forming the gate structure.

10. A method comprising:
forming an isolation region abutting an active region in a substrate, the isolation region having a recessed region set back from a top surface of the isolation region;
forming a high-k dielectric layer over the active region but not over the recessed region of the isolation region;
forming a gate structure over the high-k dielectric layer; and
forming gate spacers at opposite sidewalls of the gate structure and over the high-k dielectric layer.

11. The method of claim 10, wherein forming the high-k dielectric layer comprises:
depositing a high-k dielectric layer over the isolation region and the active region; and
etching the high-k dielectric layer to remove a portion of the high-k dielectric layer from the recessed region of the isolation region.

12. The method of claim 11, wherein the portion of the high-k dielectric layer is in contact with a sidewall of the active region.

13. The method of claim 11, wherein etching the high-k dielectric layer is performed by using a patterned photoresist as an etch mask.

14. The method of claim 10, wherein the recessed region of the isolation region is adjacent to the active region.

15. The method of claim 10, further comprising:
patterning the high-k dielectric layer into a gate dielectric layer by using the gate spacers and the gate structure as an etch mask.

16. The method of claim 15, further comprising:
after patterning the high-k dielectric layer into the gate dielectric layer, replacing the gate structure with a metal gate structure.

17. An integrated circuit (IC) structure comprising:
a shallow trench isolation (STI) region abutting an active region in a semiconductor substrate;
a first gate structure over the active region, the first gate structure comprising a high-k gate dielectric layer and a gate metal layer over the high-k gate dielectric layer; and
a second gate structure over the STI region, wherein in a cross-sectional view taken along a first direction perpendicular to a longitudinal axis of the second gate structure, the second gate structure comprises a gate metal layer in contact with the STI region.

18. The IC structure of claim 17, wherein in the cross-sectional view the second gate structure is free of a high-k gate dielectric layer.

19. The IC structure of claim 17, wherein in the cross-sectional view the gate metal layer of the first gate structure has a bottom surface higher than a bottom surface of the gate metal layer of the second gate structure.

20. The IC structure of claim 17, wherein in a cross-sectional view taken along a second direction parallel with the longitudinal axis of the second gate structure, the second gate structure comprises separate high-k gate dielectric layers, and a protruding portion of the gate metal layer extends through a region between the separate high-k gate dielectric layers to the STI region.
